(19) United States
(12) Patent Application Publication
(10) Pub. No.: US 2015/0060948 A1
(43) Pub. Date: Mar. 5, 2015

(54) SEMICONDUCTOR DEVICE

(71) Applicant: Renesas Electronics Corporation, Kawasaki-shi (JP)

(72) Inventors: Tohru KAWAI, Kanagawa (JP); Yutaka AKIYAMA, Kanagawa (JP); Yasutaka NAKASHIBA, Kanagawa (JP)

(73) Assignee: RENESAS ELECTRONICS CORPORATION

(21) Appl. No.: 14/472,665

(22) Filed: Aug. 29, 2014

(30) Foreign Application Priority Data
Sep. 2, 2013 (JP) 2013-181298

(51) Int. Cl. H01L 29/778; H01L 29/205; H01L 29/201; H01L 29/40; H01L 29/20

(52) U.S. Cl. CPC H01L 29/7787; H01L 29/402; H01L 29/2003; H01L 29/201; H01L 29/205
USPC 257/194

(57) ABSTRACT

A field plate causes excessive gate capacitance that interferes with high-speed transistor switching. To suppress the excessive gate capacitance, an aperture includes a first side wall positioned on the side of a drain electrode, and a second side wall positioned on the side of a source electrode. A gate electrode at the same time includes a first side surface facing opposite the drain electrode as seen from a plan view. The first side surface of the gate electrode is positioned on the inner side of the first side wall and the second side wall as seen from a flat view. Moreover, a portion of a first field plate is embedded between the first side surface and the first side wall. The gate electrode and the first field plate are electrically insulated by a first insulation member.

### CROSS-REFERENCE TO RELATED APPLICATIONS

The disclosure of Japanese Patent Application No. 2013-181298 filed on Sep. 2, 2013 including the specification, drawings and abstract is incorporated herein by reference in its entirety.

### BACKGROUND

The present invention relates to a semiconductor device and relates in particular to technology applicable for example to power devices.

Transistors configured from group-III nitride semiconductors are in some cases utilized in power devices. Transistors configured from group-III nitride semiconductors are disclosed in Japanese Unexamined Patent Application Publication No. 2009-246247 and Japanese Unexamined Patent Application Publication No. 2010-67816. A field plate is mounted on the side of the gate electrodes in the transistors disclosed in Japanese Unexamined Patent Application Publication No. 2009-246247 and Japanese Unexamined Patent Application Publication No. 2010-67816, in order to alleviate the internal electrical field of the transistor.

In recent years, on the other hand, gate electrodes are being manufactured in a variety of structures. Japanese Unexamined Patent Application Publication No. Hei6 (1994)-283718 and Japanese Unexamined Patent Application Publication No. Hei5 (1993)-326861 disclose a gate electrode sub-divided into plural gate electrodes on a channel. The application of different voltages to the multiple sub-divided gate electrodes is disclosed in Japanese Unexamined Patent Application Publication No. Hei6 (1994)-283718. Japanese Unexamined Patent Application Publication No. Hei5 (1993)-326861 discloses multiple input type logic gate circuits comprised of sub-divided gate electrodes.

### SUMMARY

A field plate is in some cases mounted on the side of the gate electrode in group-III nitride semiconductor HEMT (High Mobility Electron Transistors) having a gate recess (aperture) structure in order to alleviate the internal electrical field. However, the gate capacitance becomes large due to these types of field plates, which causes problems in the transistor high-speed switching operation. Other problems and novel features will become readily apparent from the description in these specifications and the attached drawings.

According to one aspect of the present invention, a recess includes a first side wall placed on the side of the drain electrode, and a second side wall placed on the side of the source electrode. The gate electrode at the same time includes a first side surface facing opposite the drain electrode as seen from a plan view. The first side surface of the gate electrode is positioned on the inner side of the first side wall and the second side wall as seen from a plan view. Further, a portion of the field plate is embedded between the first side surface and the first side wall. An insulation member electrically insulates the gate electrode and the field plate.

According to another aspect of the present invention, an insulation member electrically insulates the gate electrode and the field plate. The drain electrode, the source electrode, the gate electrode, and the field plate are at the same time respectively electrically coupled to a drain pad, a source pad, a gate pad, and an electrode pad. The electrode pad is formed at a position different from the source pad, the drain pad, and the gate pad.

According to one aspect of the present invention, different voltages can be applied to the gate electrode and the field plate.

### BRIEF DESCRIPTION OF THE DRAWINGS

FIG. 1 is a cross-sectional view showing the semiconductor device of the first embodiment;

FIG. 2 is an enlarged view of the vicinity of the gate electrode of FIG. 1;

FIG. 3 is a plan view showing the planar layout of the semiconductor electrode of the first embodiment;

FIG. 4 is a cross-sectional view showing the manufacturing method of the semiconductor device shown in FIG. 1;

FIG. 5 is a cross-sectional view showing the manufacturing method of the semiconductor device shown in FIG. 1;

FIG. 6 is a cross-sectional view showing the manufacturing method of the semiconductor device shown in FIG. 1;

FIG. 7 is a cross-sectional view showing the manufacturing method of the semiconductor device shown in FIG. 1;

FIG. 8 is a cross-sectional view showing the manufacturing method of the semiconductor device shown in FIG. 1;

FIG. 9 is a cross-sectional view showing the manufacturing method of the semiconductor device shown in FIG. 1;

FIG. 10 is a cross-sectional view showing the manufacturing method of the semiconductor device shown in FIG. 1;

FIG. 11 is a cross-sectional view showing the manufacturing method of the semiconductor device shown in FIG. 1;

FIG. 12 is a drawing showing an example of a variation of FIG. 1;

FIG. 13 is a drawing showing an example of a variation of FIG. 1;

FIG. 14 is a drawing showing an example of a variation of FIG. 1;

FIG. 15 is a cross-sectional view showing the semiconductor device of the second embodiment;

FIG. 16 is a cross-sectional view showing the manufacturing method of the semiconductor device shown in FIG. 15;

FIG. 17 is a cross-sectional view showing the manufacturing method of the semiconductor device shown in FIG. 15;

FIG. 18 is a cross-sectional view showing the manufacturing method of the semiconductor device shown in FIG. 15;

FIG. 19 is a cross-sectional view showing the manufacturing method of the semiconductor device shown in FIG. 15;

FIG. 20 is a cross-sectional view showing the manufacturing method of the semiconductor device shown in FIG. 15;

FIG. 21 is a cross-sectional view showing the manufacturing method of the semiconductor device shown in FIG. 15;

FIG. 22 is a circuit diagram showing the electronic device containing the semiconductor device shown in FIG. 1;

FIG. 23 is a circuit diagram showing the electronic device containing the semiconductor device shown in FIG. 1; and

FIG. 24 is a circuit diagram showing the electronic device containing the semiconductor device shown in FIG. 1.

### DETAILED DESCRIPTION

The present embodiment is hereinafter described while referring to the accompanying drawings. In all of the drawings the same reference numerals are assigned to the same structural elements and redundant descriptions are omitted.

### First Embodiment

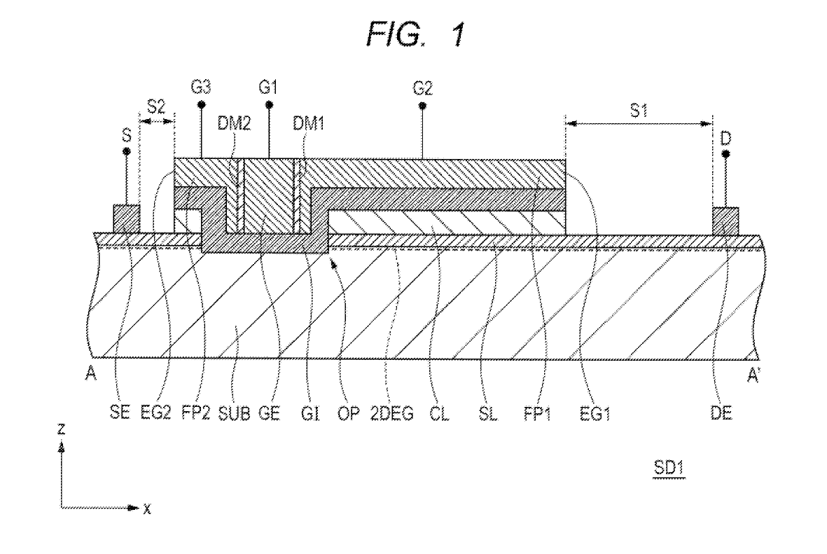

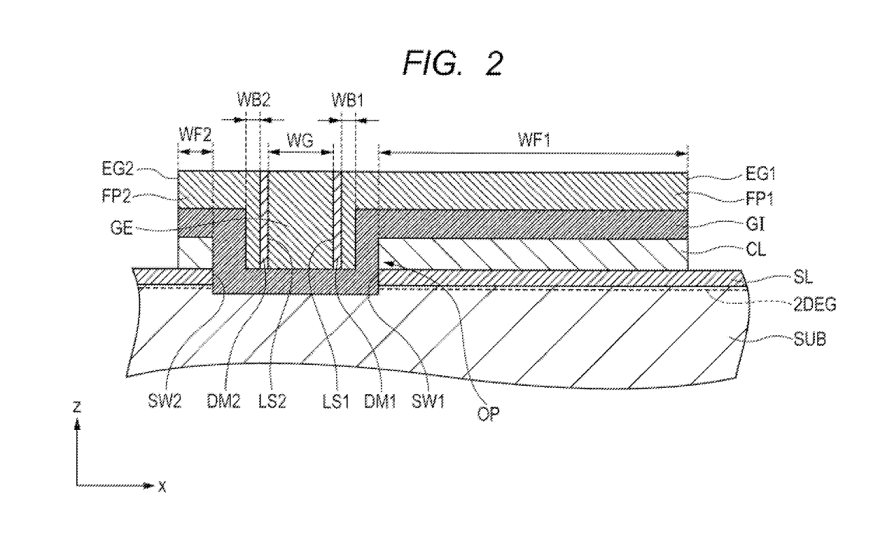

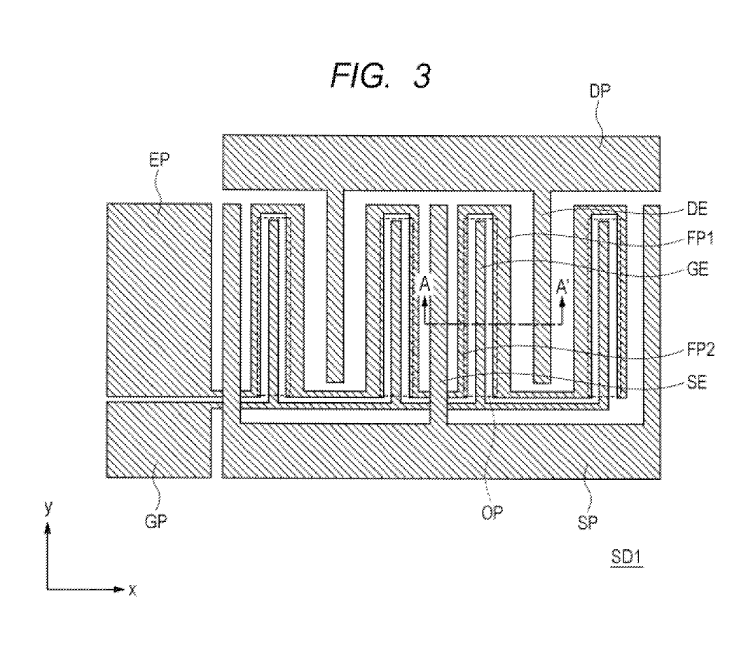

FIG. 1 is a cross-sectional view showing the semiconductor device SD1 of the first embodiment. FIG. 2 is an enlarged view of the vicinity of the gate electrode GE of FIG. 1. FIG. 3 is a plan view showing the planar layout of the semiconductor electrode SD1. FIG. 1 is a cross-sectional view taken along lines A-A′ in FIG. 3.

The semiconductor device SD1 of the present embodiment includes a substrate SUB (first group-III nitride semiconductor layer), a semiconductor layer SL (second group-III nitride semiconductor layer), a cap layer CL (insulation layer), a drain electrode DE, a source electrode SE, a gate electrode GE, and a first field plate FP1. The semiconductor layer SL is formed over the substrate SUB. The cap layer CL contains a first surface and a second surface. The second surface faces opposite the semiconductor layer SL by way of the first surface. The second surface includes an aperture OP. The bottom of the aperture OP reaches at least to the inner section of the semiconductor layer SL. The drain electrode DE and the source electrode SE are electrically coupled to the semiconductor layer SL. Moreover, the drain electrode DE and the source electrode SE also face mutually opposite each other by way of the aperture OP as seen from a plan view. At least one section of the gate electrode GE faces opposite the substrate SUB by way of the bottom of the aperture OP in the depth direction of the aperture OP. At least a portion of the first field plate FP1 faces opposite the semiconductor layer SL between the drain electrode DE and the aperture OP as seen from a plan view by way of the cap layer CL.

In the present embodiment, the aperture OP includes a first side wall SW1 and a second side wall SW2. The first side wall SW1 is positioned on the side of the drain electrode DE. The second side wall SW2 is positioned on the side of the source electrode SE. The gate electrode GE includes a first side surface LS1. The first side surface LS1 is positioned on the inner side of the first side wall SW1 and the second side wall SW2. A portion of the first field plate FP1 is embedded between the first side surface LS1 and the first side wall SW1. The gate electrode GE and the first field plate FP1 are electrically insulated by the first insulation member DM1. At least a portion of the first insulation member DM1 is positioned on the inner side of the first side wall SW1 and the second side wall SW2 as seen from a plan view.

The gate electrode GE and the first field plate FP1 are electrically insulated in the semiconductor device SD1 by the first insulation member DM1. Therefore, different voltages can be applied to the gate electrode GE and the first field plate FP1. Consequently, a voltage can be applied to the gate electrode GE and the first field plate FP1 so as to alleviate the electrical field across the gate-drain while suppressing the gate capacitance of the gate electrode GE. Moreover, in the semiconductor device SD1, a portion of the first field plate FP1 is embedded between the first side surface LS1 and the first side wall SW1. Consequently, a voltage can be applied to the first field plate FP1 so as to suppress the ON-resistance in the vicinity of the first side wall SW1 of the aperture OP.

Also in the present embodiment, the semiconductor device SD1 includes a drain pad DP, a source pad SP, a gate pad GP, and an electrode pad EP. The drain pad DP, the source pad SP, the gate pad GP, and the electrode pad EP are respectively electrically coupled to the drain electrode DE, the source electrode SE, the gate electrode GE, and the first field plate FP1. The electrode pad EP is mounted at a position different from the source pad SP, the drain pad DP, and the gate pad GP.

In the semiconductor device SD1, different voltages can be respectively applied by way of the gate pad GP and the electrode pad EP to the gate electrode GE and the first field plate EP1. A voltage can be applied to the gate electrode GE and the first field plate FP1 so as to alleviate the electrical field across the gate-drain while suppressing the gate capacitance of the gate electrode GE. Moreover, a voltage can be applied to the first field plate FP1 so as to suppress the ON-resistance in the vicinity of the first side wall SW1 of the aperture OP.

The semiconductor device SD1 is described next in detail while referring to FIG. 1 through FIG. 3. FIG. 1 through FIG. 3 defines the X coordinate direction, the Y coordinate direction, and the Z coordinate direction by way of the right-handed Cartesian coordinates. The drain electrode DE and the source electrode SE face opposite each other along the X axis. The gate electrode GE extends along the y axis. The thickness direction of the substrate SUB is along the z axis.

A transistor unit of the semiconductor device SD1 is described using FIG. 1 and FIG. 2. The substrate SUB is a group-III nitride semiconductor (for example, gallium nitride (GaN)) substrate. More specifically, the substrate SUB is a silicon substrate formed from deposited group-III nitride semiconductor.

The semiconductor layer SL is formed over the substrate SUB. The semiconductor layer SL is for example a group-III nitride semiconductor layer (for example, aluminum gallium nitride (AlGaN)). The semiconductor layer SL forms a heterojunction with the surface of the substrate SUB. The surface of the substrate SUB emits 2DEG (a two-dimensional electron gas) by way of this heterojunction.

The cap layer CL is formed over the semiconductor layer SL. The cap layer CL is an insulation layer (for example silicon nitride (SiN)). The cap layer CL includes a first surface and a second surface. The second surface faces opposite the semiconductor layer SL by way of the first surface. The second surface includes an aperture OP. The bottom of the aperture OP reaches the interior section of at least the semiconductor layer SL. In this way, no 2DEG is formed at the region overlapping the aperture OP as seen from a plan view. A transistor unit of the semiconductor device SD1 is a normally-off transistor. In the present embodiment, the aperture OP extends through the cap layer CL and the semiconductor layer SL, and the bottom of the aperture OP reaches the interior section of the substrate SUB.

The semiconductor device SD1 further includes a gate insulation film GI. The gate insulation film GI is formed from a region overlapping the cap layer CL as seen from a plan view to a region overlapping the aperture OP as seem from a plan view. The gate insulation film GI is formed along the contour of the aperture OP and the surface of the cap layer CL. The gate insulation film GI is formed for example from aluminum oxide (Al₂O₃)).

The drain electrode DE and the source electrode SE are electrically coupled to the semiconductor layer SL. In the present embodiment, the drain electrode DE and the source electrode SE are formed over the surface of the semiconductor layer SL. The drain electrode DE and the source electrode SE face mutually opposite each other by way of the aperture OP as seen from a plan view. The drain electrode DE and the source electrode SE are formed from metal (for example, titanium nitride (TiN)).

The gate electrode GE is formed between the drain electrode DE and the source electrode SE as seen from a plan view. At least a portion of the gate electrode GE faces opposite the substrate SUB by way of the aperture OP in the depth direction of aperture OP. In the present embodiment, the gate electrode GE is formed on the inner side of the aperture OP as seen from a plan view. The gate electrode GE is formed from metal (for example, titanium nitride (TiN)).

The first field plate FP1 is formed between the drain electrode DE and the gate electrode GE as seen from a plan view. At least a portion of the first field plate FP1 faces opposite the substrate SUB by way of the cap layer CL between the aperture OP and the drain electrode DE as seen from a plan view. The first field plate FP1 is formed from the same material as the gate electrode GE (for example, titanium nitride (TiN)).

The semiconductor device SD1 further includes a second field plate FP2. The second field plate FP2 is formed between the source electrode SE and the gate electrode GE as seen from a plan view. At least a portion of the second field plate FP2 faces opposite the substrate SUB by way of the cap layer CL between the aperture OP and the source electrode SE as seen from a plan view. The second field plate FP2 is formed from the same material as the gate electrode GE (for example, titanium nitride (TiN)).

The aperture OP includes a first side wall SW1 and a second side wall SW2. The first side wall SW1 is positioned on the side of the drain electrode DE. The second side wall SW2 is positioned on the side of the source electrode SE. The gate electrode GE on the other hand, contains a first side surface LS1 and a second side surface LS2. The first side surface LS1 faces opposite the drain electrode DE as seen from a plan view. The second side surface LS2 faces opposite the source electrode SE as seen from a plan view. The first side surface LS1 and the second side surface LS2 are positioned on the inner side of the first side wall SW1 and the second side wall SW2 as seen from a plan view.

A portion of the first field plate FP1 is embedded between the first side wall SW1 and the first side surface LS1 in the semiconductor SD1. A portion of the second field plate FP2 is in the same way embedded between the second side wall SW2 and the second side surface LS2. Moreover, the gate electrode GE and the first field plate FP1 are electrically coupled by the first insulation member DM1. The gate electrode GE and the second field plate FP2 are in the same way electrically coupled by the second insulation member DM2. At least a portion of the first insulation member DM1 is positioned on the inner side of the first side wall SW1 and the second side wall SW2. At least a portion of the second insulation member DM2 is in the same way positioned on the inner side of the first side wall SW1 and the second side wall SW2 as seen from a plan view. In the present embodiment, the first insulation member DM1 is positioned between the first side surface LS1 and the first side wall SW1 as seen from a plan view. The second insulation member DM2 is in the same way positioned between the second side surface LS2 and the second side wall SW2 as seen from a plan view.

The above described structure allows applying different voltages to the gate electrode GE, the first field plate FP1, and the second field plate FP2. Consequently, voltages can be applied to the gate electrode GE, the first field plate FP1, and the second field plate FP2 so as to alleviate the electrical field between the gate-drain and between the gate-source, while suppressing the gate capacitance of the gate electrode GE. In addition, voltages can be applied to the first field plate FP1 and the second field plate FP2 so as to suppress the on-resistance in the vicinity of the first side wall SW1 and in the vicinity of the second side wall SW2 of the aperture OP.

In the present embodiment, the first field plate FP1 and the drain electrode DE are formed mutually separated along the x axis direction. The second field plate FP2 and the source electrode SE are in the same way formed mutually separated along the x axis direction. In the present embodiment, the first field plate FP1 includes a first edge section EG1. The second field plate FP2 in the same way includes a second edge section EG2. The first edge section EG1 is an edge section facing opposite the drain electrode DE in the x axis direction as seen from a plan view. The second edge section EG2 is an edge section facing opposite the source electrode SE in the x axis direction as seen from a plan view. The gap S1 between the first edge section EG1 and the drain electrode DE is larger than the gap S2 between the second edge section EG2 and the source drain electrode SE.

The first side surface LS1 in the present embodiment is located more towards the drain electrode DE side than the center of the aperture OP along the x axis as seen from a plan view. The second side surface LS2 is also located more towards the source electrode SE side than the center of the aperture OP along the x axis as seen from a plan view. Also in this embodiment, the width WG of the gate electrode GE is formed wider than the width WB1 of the section so that a portion of the first field plate FP1 is embedded between the first side surface LS1 and the first side wall SW1, along the direction where the first side wall SW1 and the second side wall SW2 face opposite each other as seen from a plan view. The width of the gate electrode GE at the same time is formed wider than the width WB2 of the section so that a portion of the second field plate FP2 is embedded between the second side surface LS2 and the second side wall SW2 along the direction where the first side wall SW1 and the second side wall SW2 face opposite each other as seen from a plan view.

The width WF1 (width of the first field plate FP1) between the first side wall SW1 and the first edge section EG1 is wider than the width WF2 (width of second field plate FP2) between the second side wall SW2 and the second edge section EG2. Moreover, the aperture OP is closer to the source electrode SE side than the drain electrode DE along the x axis direction. In this case, a large distance can be set between the gate electrode GE and the drain electrode DE. Consequently, a large voltage resistance can be set between the gate electrode GE and the drain electrode DE.

The layout of the electrodes on the semiconductor device SD1 is described next while referring to FIG. 3. In FIG. 3, four transistor units are placed in parallel along the x axis. The number of these transistor units is not limited to four, and may be one or two or more (other than four).

In the present embodiment, the first field plate FP1 and the second field plate FP2 are electrically coupled to the electrode pad EP. In other words, the first field plate FP1 and the second field plate FP2 are electrically coupled to the same electrode pad. The drain pad DP and the source pad SP face opposite each other by way of the gate electrode GE, the first field plate FP1, and the second field plate FP2 as seen from a plan view. The gate pad GP is positioned towards the side of the source pad SP along the x-axis. The electrode pad EP is positioned towards the side of the gate pad GP along the y axis. More specifically, the electrode pad EP is positioned between the drain pad DP and the source pad SP along the y axis. The gate pad GP may be positioned towards the side of the drain pad DP rather than the side of the source pad SP.

In the present embodiment, the drain electrode DE extends from the side of the drain pad DP towards the source pad SP side as seen from a plan view. The source electrode SE in the same way extends from the source pad SP side towards the drain pad DP side as seen from a plan view. The gate electrode GE is positioned between the drain electrode DE and the source electrode SE as seen from a plan view. Further in the present embodiment, as seen from a plan view, a meandering pattern is formed so as to weave between the drain electrode DE and gate electrode GE, and between the source electrode SE and the gate electrode GE as shown in FIG. 3. The meandering pattern forms a first field plate FP1 between the drain electrode DE and the gate electrode GE as shown in FIG. 3. A meandering pattern in the same way also forms a second field plate FP2 between the source electrode SE and the gate electrode GE.

The first field plate FP1 and the second field plate FP2 may also be coupled to mutually different electrode pads. In this case, the electrode pad electrically coupled to the first field plate FP1 and the electrode pad electrically coupled to the second field plate FP2 are mounted at positions different from the drain pad DP, the source pad SP, and the gate pad GP. The electrode pad electrically coupled to the first field plate FP1 and the electrode pad electrically coupled to the second field plate FP2 are at this same time are mounted at mutually different positions.

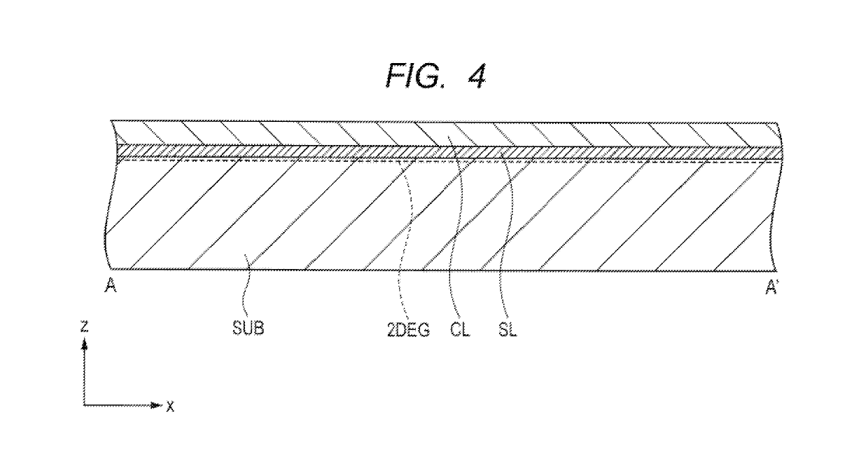

The method for manufacturing the semiconductor device SD1 is described next while referring to FIG. 4 through FIG. 11. FIG. 4 through FIG. 11 are cross-sectional views showing the method for manufacturing the semiconductor device SD1.

A substrate SUB is first of all prepared. A group-III nitride semiconductor layer (for example, gallium nitride (GaN)) is formed over the surface of the substrate SUB. Next, a group-III nitride semiconductor layer SL of (for example, aluminum gallium nitride (AlGaN)) is formed over the surface of the substrate SUB by epitaxial growth (for example MOVPE: Metal-Organic Vapor Phase Epitaxy). A heterojunction is in this way formed between the surface of the substrate SUB and the semiconductor layer SL. This heterojunction emits 2DEG at the surface of the substrate SUB. A cap player CL of an insulation piece (for example silicon nitride (SiN)) is next formed over the surface of the semiconductor layer SL (FIG. 4).

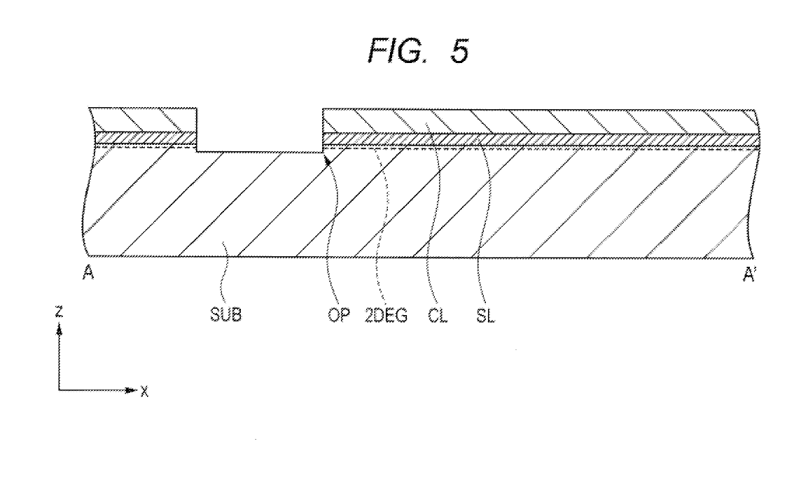

The aperture OP is next formed as shown in FIG. 5. The aperture OP is formed for example by dry etching. The aperture OP passes through the cap layer CL and the bottom of the aperture OP reaches at least the inner section of the semiconductor layer SL. In the present embodiment, the aperture OP passes through the semiconductor layer SL in addition to the cap layer CL and the bottom of the aperture OP reaches the inner section of the substrate SUB.

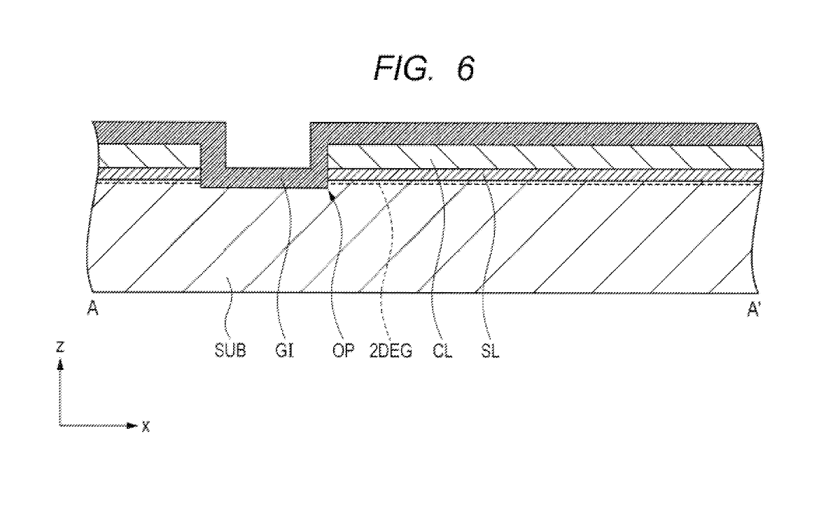

Next, gate insulation film GI (for example aluminum oxide (Al₂O₃)) is deposited as shown in FIG. 6. The gate insulation film GI is isotropically deposited as shown in FIG. 6. The gate insulation film GI is formed along the contours of the surface of the cap layer CL and the aperture OP.

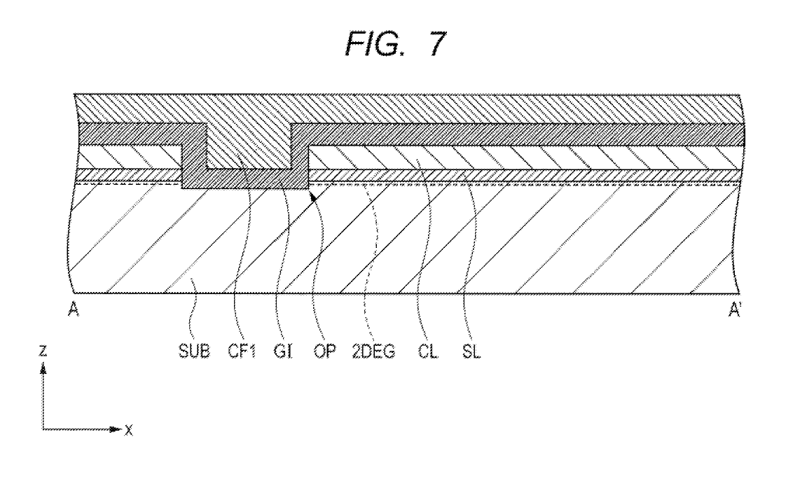

Next, a conductive film CF1 is deposited over the gate insulation film GI (FIG. 7). The conductive film CF1 is formed from metal (for example, titanium nitride (TiN)). Sputtering is for example utilized to deposit the conductive film CF1.

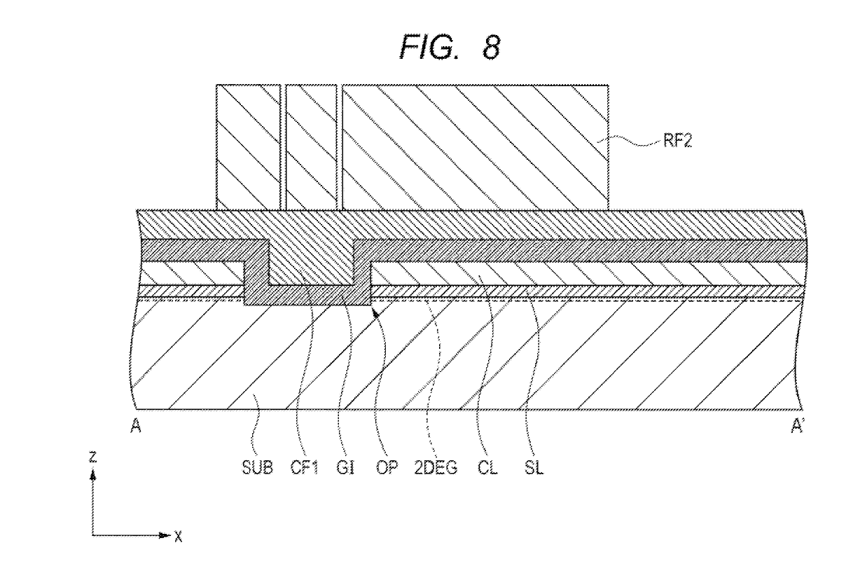

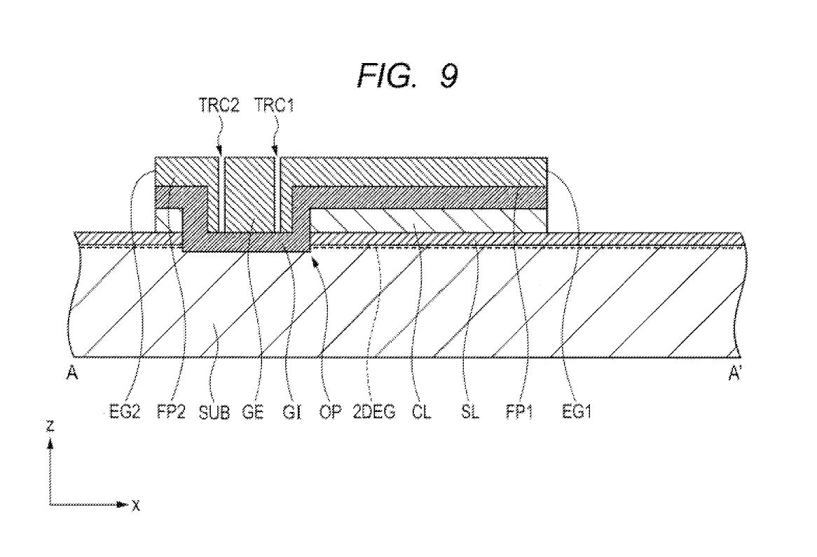

A resist film RF2 is next formed as shown in FIG. 8. Next, the conductive film CF1, the semiconductor layer SL, and the cap layer CL are etched utilizing the resist film RF2 as a mask. More specifically, along with forming a groove TRC1 and a groove TRC2 between the first side wall SW1 and the second side wall SW2 as seen from a plan view, the conductive film CF1, the semiconductor layer SL, and the cap layer CL are patterned on the outer side of the aperture OP as seen from a plan view. The gate electrode GE, the first field plate FP1, and the second field plate FP2 are consequently formed as shown in FIG. 9. The etching for forming the groove TRC1 and the groove TRC2, and the etching for patterning the conductive film CF1, the gate insulation film GI, and the cap layer CL on the outer side of the aperture OP are performed by the same process in the present embodiment.

The widths of the groove TRC1 and the groove TRC2 may be any value provided that the latter described insulation film DF is embedded in at least a portion of the groove TRC1 or at least a portion of the groove TRC2. The groove TRC1 and the groove TRC2 pierce through the conductive film CF1. The bottom of the groove TRC1 and the bottom of the groove TRC2 reach at least the surface of the gate insulation film GI. The bottom of the groove TRC1 and the bottom of the groove TRC2 may also reach the inner section of the gate insulation film GI without stopping at the surface of the gate insulation film GI.

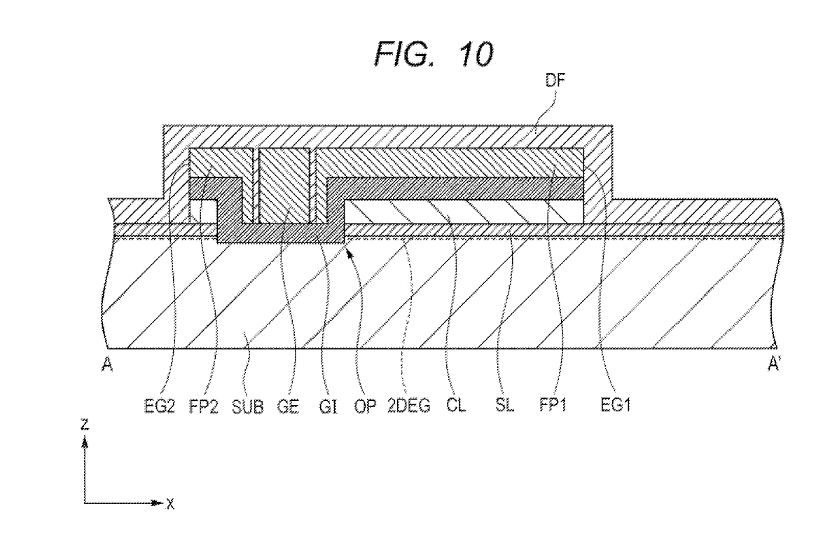

The resist film RF 2 is next stripped away. The insulation film DF (for example silicon dioxide (SiO₂)) is deposited as shown in FIG. 10. The insulation film DF is in this way embedded into the groove TRC1 and the groove TRC2. The section where the insulation film DF is embedded into the groove TRC1 and the section where the insulation film DF is embedded into the groove TRC2 in this way respectively form the first insulation member DM1 and the second insulation member DM2 in a subsequent process.

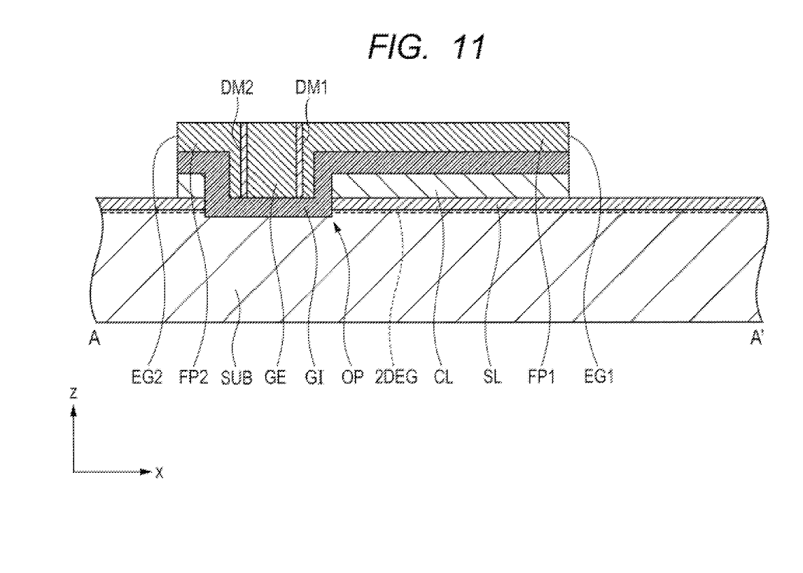

Next, the insulation film DF is stripped away except for the portion embedded into the groove TRC1 and groove TRC2 (FIG. 11). The first insulation member DM1 and the second insulation member DM2 are in this way respectively formed as shown in FIG. 11.

The drain electrode DE and the source electrode SE are next formed. The manufacture of the semiconductor device SD1 is completed in this way.

In the present embodiment, the conductive film CF1 is formed from the aperture OP to the side of the drain electrode DE as seen from a plan view. A groove TRC1 is formed on the inner side of the first side wall SW1 and the second side wall SW2 in the conductive film CF1 as seen from a plan view. The first insulation member DM1 is embedded in at least a portion of the groove TRC1. The conductive film CF1 as shown in FIG. 1, forms a gate electrode GE at the side of the source electrode SE relative to the first insulation member DM1 as seen from a plan view. The conductive film CF1 at the same time forms a first field plate FP1 on the side of the drain electrode DE relative to the first insulation member DM1 as seen from a plan view.

In the present embodiment, the conductive film CF1 is formed in the same way from the aperture OP to the side of the source electrode SE as seen from a plan view. A groove TRC2 is formed on the inner side of the first side wall SW1 and the second side wall SW2 in the conductive film CF1 as seen from a plan view. The second insulation member DM2 is embedded in at least a portion of the groove TRC2. The conductive film CF1 as shown in FIG. 1, forms a gate electrode GE on the side of the drain electrode DE relative to the second insulation member DM2 as seen from a plan view. The conductive film CF2 forms a second field plate FP2 at the same time on the side of the source electrode SE relative to the second insulation member DM2 as seen from a plan view.

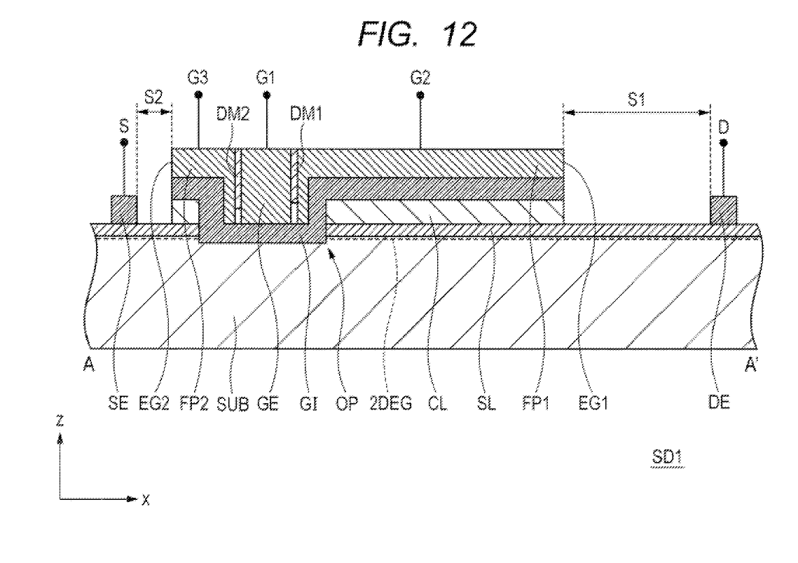

In the present embodiment, the first insulation member DM1 does not require embedding into the entire groove TRC1. The first insulation member DM1 may be configured as shown in FIG. 12. FIG. 12 is a drawing showing a variation of FIG. 1. In FIG. 12, the first insulation member DM1 is embedded in a portion of the groove TRC1. In other words, the first insulation member DM1 is embedded in the groove TRC1 so as to form a gap in the inner section of the groove TRC1. The gap in the inner section of the groove TRC1 electrically insulates the gate electrode GE and the first field plate FP1 even if the first insulation member DM1 is not embedded into the entire groove TRC1. Therefore there is no need to embed the first insulation member DM1 into the entire groove TRC1. The second insulation member DM2 in the same way need not be embedded into the entire groove TRC2. The second insulation member DM2 may also be embedded so as to form a gap in the inner section of the groove TRC2 the same as the first insulation member DM1. The same effect can also be obtained in the semiconductor device SD1 shown in FIG. 1, even for the semiconductor device SD1 shown in FIG. 12.

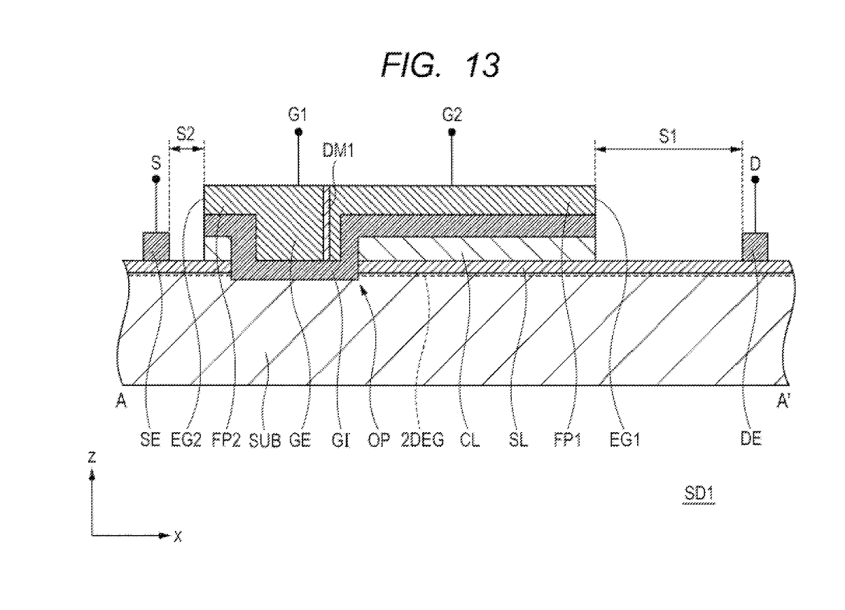

In the present embodiment, there is no need to utilize both a first insulation member DM1 and a second insulation member DM2. As shown in FIG. 13, the second insulation member DM2 need not be as utilized. FIG. 13 shows a variation of the structure in FIG. 1.

In FIG. 13, there is no second insulation member DM2 mounted between the gate electrode GE and the second field plate FP2. The same voltage (G1) is therefore applied to the gate electrode GE and the second field plate FP2. Also in this case, different voltages can be applied to the gate electrode GE (second field plate FP2) and the first field plate FP1. Consequently, a voltage can be applied to the gate electrode GE (second field plate FP2) and the first field plate FP1 so as to alleviate the electrical field between the gate-drain while suppressing the gate capacitance of gate electrode GE. In addition, a voltage can be applied to the first field plate FP1 so as to suppress the on-resistance in the vicinity of the first side wall SW1 of the aperture OP.

In the present embodiment, forming only the second insulation member DM2 is sufficient and the first insulation member DM1 need not be formed. Even in this case, different voltages can be applied to the gate electrode GE (first field plate FP1) and the second field plate FP2. Consequently, a voltage can be applied to the gate electrode GE (first field plate FP1) and the second field plate FP2 so as to alleviate the electrical field between the gate-source while suppressing the gate capacitance of gate electrode GE. In addition, a voltage can be applied to the second field plate FP2 so as to suppress the on-resistance in the vicinity of the second side wall SW2 of the aperture OP.

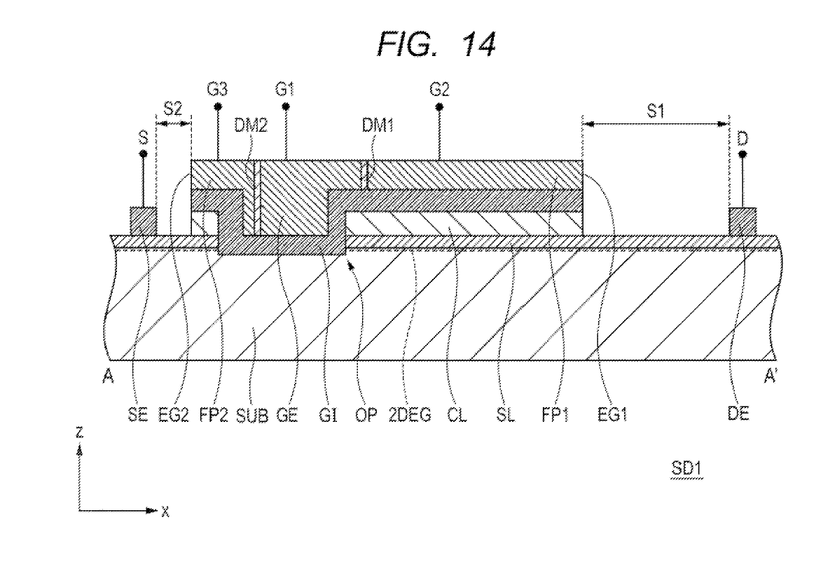

In the present embodiment, there is no need to position the first insulation member DM1 on the inner side of the first side wall SW1 and the second side wall SW2 as shown from a plan view. The first insulation member DM1 may be formed as shown in FIG. 14. FIG. 14 is a drawing showing an example of variation of the structure in FIG. 1.

In FIG. 14, the first insulation member DM1 is positioned on the outer side of the first side wall SW1 and the second side wall SW2 as seen from a plan view. The first side wall SW1 and the second side wall SW2 of the semiconductor device SD1 as shown in FIG. 14 are respectively the same as the first side wall SW1 and the second side wall SW2 shown in FIG. 2. Even in this case, different voltages can be applied to the gate electrode GE, the first field plate FP1, and the second field plate FP2. Consequently, a voltage can be applied to the gate electrode GE, the first field plate FP1, and the second field plate FP2 so as to alleviate the electrical field between the gate-drain and between the gate-source while suppressing the gate capacitance of gate electrode GE.

Further in the present embodiment, the second insulation member DM2 may be positioned on the outer side of the first side wall SW1 and the second side wall SW2 as seen from a plan view, the same as for the first insulation member DM1. In another example, the first insulation member DM1 may be positioned on the inner side of the first side wall SW1 and the second side wall SW2 as seen from a plan view, while the second insulation member DM2 is positioned on the outer side of the first side wall SW1 and the second side wall 2 as seen from a plan view. In either of these cases, the different voltages can be applied to the gate electrode GE, the first field plate FP1, and the second field plate FP2. Consequently, a voltage can be applied to the gate electrode GE, the first field plate FP1, and the second field plate FP2 so as to alleviate the electrical field between the gate-drain and between the gate-source while suppressing the gate capacitance of the gate electrode GE.

### Second Embodiment

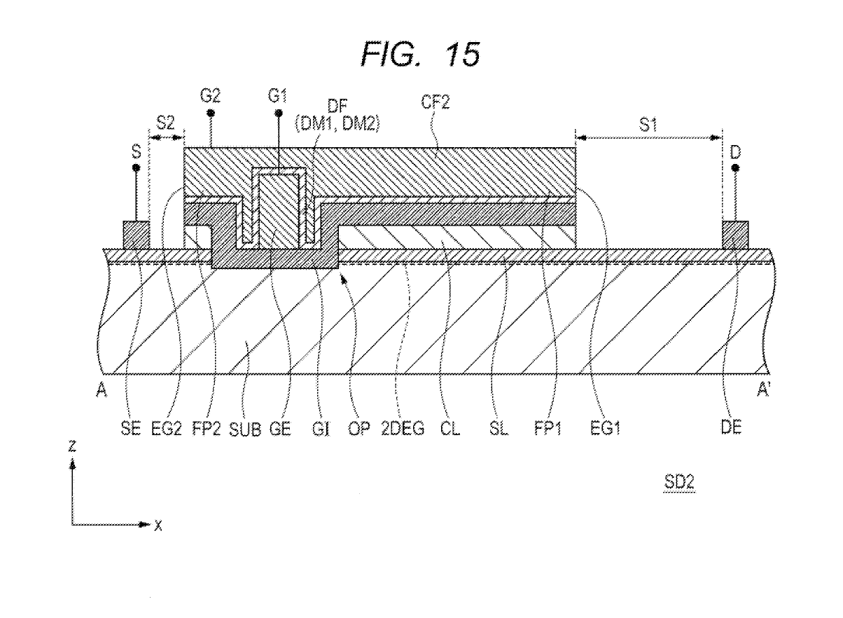

FIG. 15 is a cross-sectional view of the semiconductor device SD2 of the second embodiment. FIG. 15 corresponds to FIG. 1 shown in the first embodiment. The semiconductor device SD2 has the same structure as the semiconductor device SD1 except for the following points. In the semiconductor device SD2, an insulation film DF is formed from the inner side of the aperture OP to the outer side of the aperture OP. An insulation film DF is at the same time, formed along the gate electrode GE and the contour of the aperture OP on the inner side of the aperture OP as seen from a plan view. Further, a conductive film CF2 is formed from the inner side of the aperture OP to the outer side of the aperture OP as seen from a plan view. The conductive film CF2 at the same time covers the gate electrode GE and the insulation film DF. The first insulation member DM1 is comprised from the insulation film DF along the first side surface LS1. The insulation film DF in the same way forms a second insulation member DM2 along the second side surface LS2. The conductive film CF2 forms a first field plate FP1 from the aperture OP to the drain electrode DE as seen from a plan view. The conductive film CF2 in the same way forms a second field plate FP2 from the aperture OP to the source electrode SE as seen from a plan view. The first side surface LS1 and the second side surface LS2 of the semiconductor device SD2 shown in FIG. 15 are respectively identical to the first side surface LS1 and the second side surface LS2 shown in FIG. 2.

In the present embodiment, the insulation film DF electrically insulates the gate electrode GE and the conductive film CF2. Different voltages can therefore be applied to the gate electrode GE and the conductive film CF2. Consequently, a voltage can be applied to the gate electrode GE and the conductive film CF2 so as to alleviate the electrical field between the gate-drain and between the gate-source while suppressing the gate capacitance of the gate electrode GE. In addition, a voltage can be applied to the conductive film CF2 so as to suppress the on-resistance in the vicinity of the first side wall SW1 and the second side wall SW2 of the aperture OP. The first side wall SW1 and the second side wall SW2 of the semiconductor device SD2 shown in FIG. 15 are respectively identical to the first side wall SW1 and the second side wall SW2 shown in FIG. 2.

The insulation film DF is formed so that a groove is formed between the first side surface LS1 and the first side wall SW1. The conductive film CF2 can therefore be embedded into this groove. The insulation film DF is formed in the same way so that a groove is formed between the second side surface LS2 and the second side wall SW2. The conductive film CF2 can therefore be embedded into this groove.

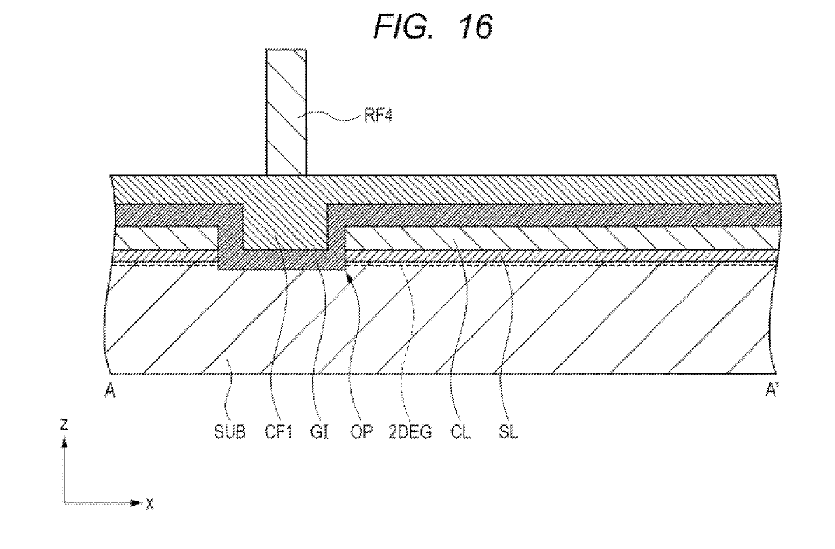

The method for manufacturing the semiconductor device SD2 is described next while referring to FIG. 16 through FIG. 21. The drawings in FIG. 16 through FIG. 21 are cross-sectional views showing the method for manufacturing the semiconductor device SD2.

The process shown in FIG. 4 through FIG. 7 is implemented the same as in the first embodiment. Next, the resist film RF4 is formed as shown in FIG. 16. The resist film RF4 is next utilized as a mask for etching the conductive film CF1. The gate electrode GE is in this way formed in the inner section of the aperture OP.

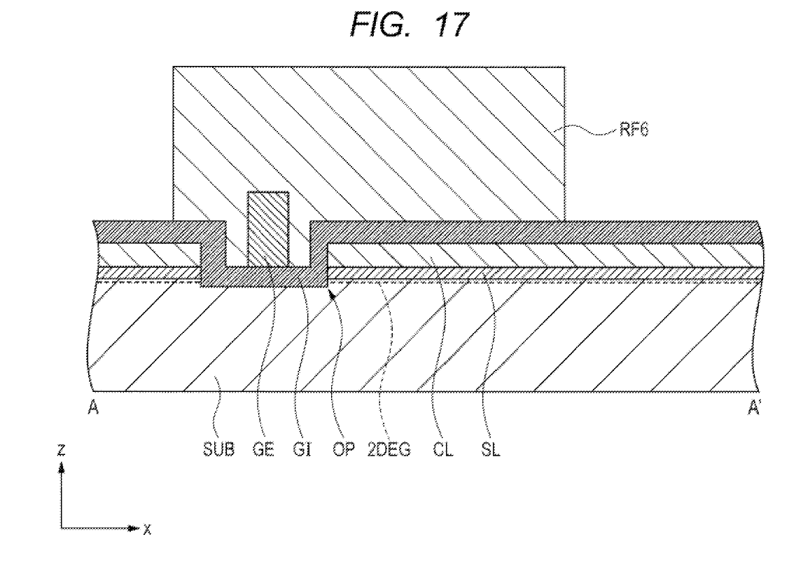

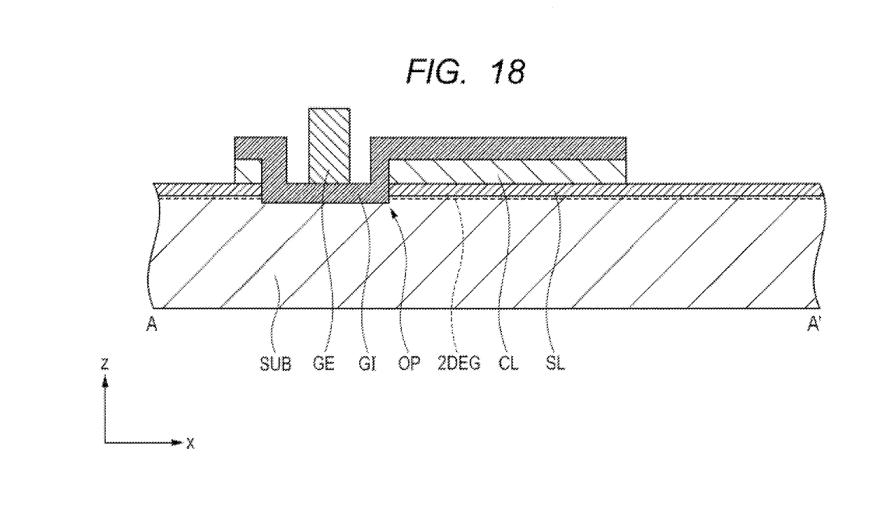

The resist film RF4 is next stripped away. The resist film RF6 is next formed as shown in FIG. 17. The gate insulation film GI and the cap layer CL are next patterned as shown in FIG. 18 utilizing the resist film RF6 as a mask.

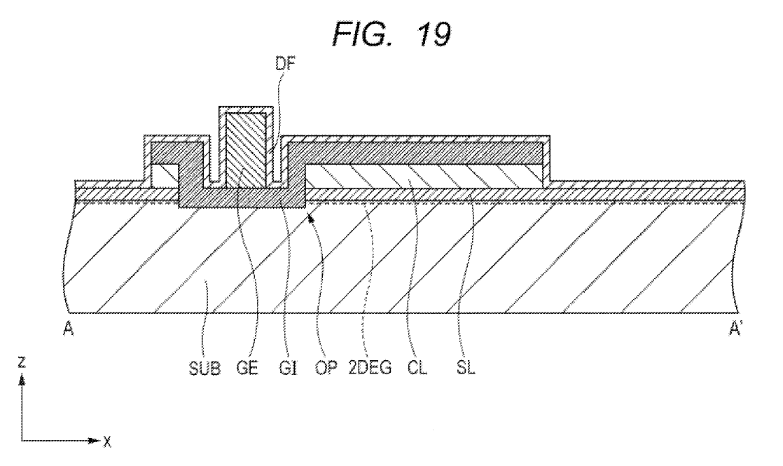

The insulation film DF (for example silicon dioxide (SiO₂)) is next deposited as shown in FIG. 19. The insulation film DF is isotropically deposited as shown in FIG. 19. The insulation film DF is therefore formed along the contours of the gate electrode GE and the aperture OP.

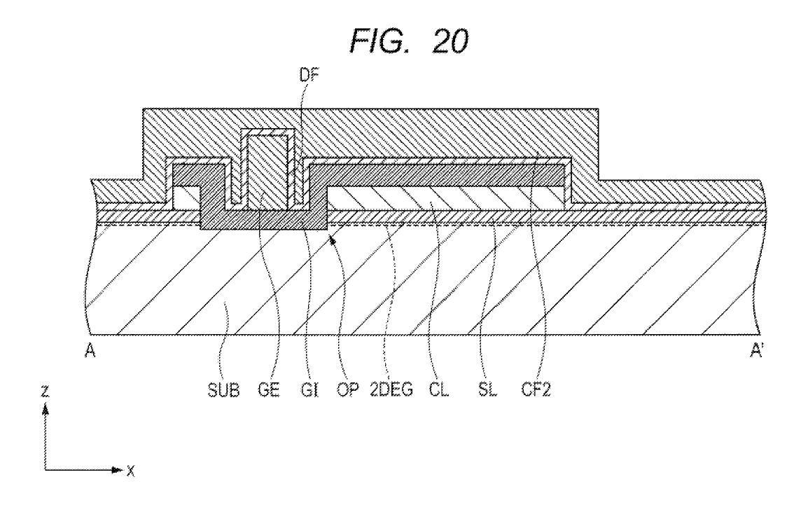

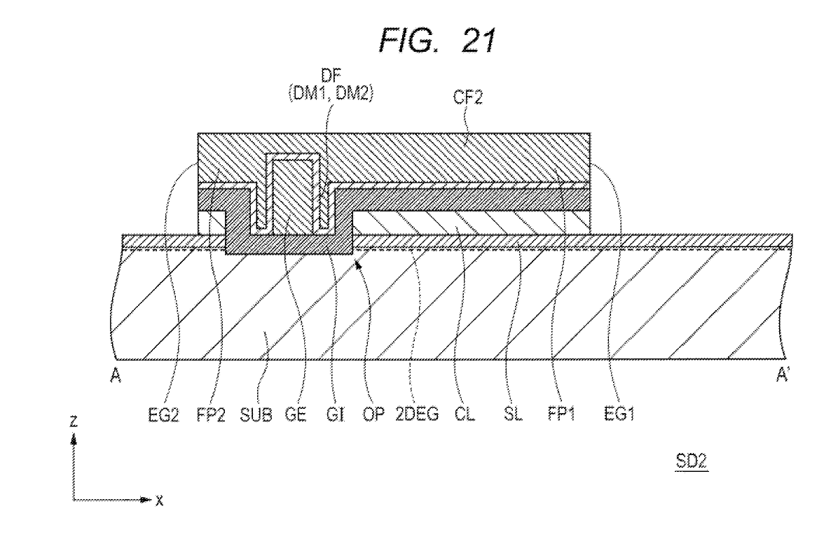

Next, the conductive film CF2 (for example, titanium nitride (TiN)) is formed over the insulation film DF (FIG. 20). Sputtering for example may be utilized to form the conductive film CF2. The conductive film CF2 and the insulation film DF are next patterned as shown in FIG. 21. The first field plate FP1 and the second field plate FP2 are formed in this way. The drain electrode DE and the source electrode SE are next formed. The semiconductor device SD2 is manufactured in this way.

In the present embodiment, different voltages can be applied to the gate electrode GE and the conductive film CF2. Consequently, a voltage can be applied to the gate electrode GE and the conductive film CF2 so as to alleviate the electrical field between the gate-drain and between the gate-source while suppressing the gate capacitance of the gate electrode GE. In addition, a voltage can be applied to the conductive film CF2 so as to suppress the ON-resistance in the vicinity of the first side wall SW1 and the vicinity of the second side wall SW2 of the aperture OP.

### Third Embodiment

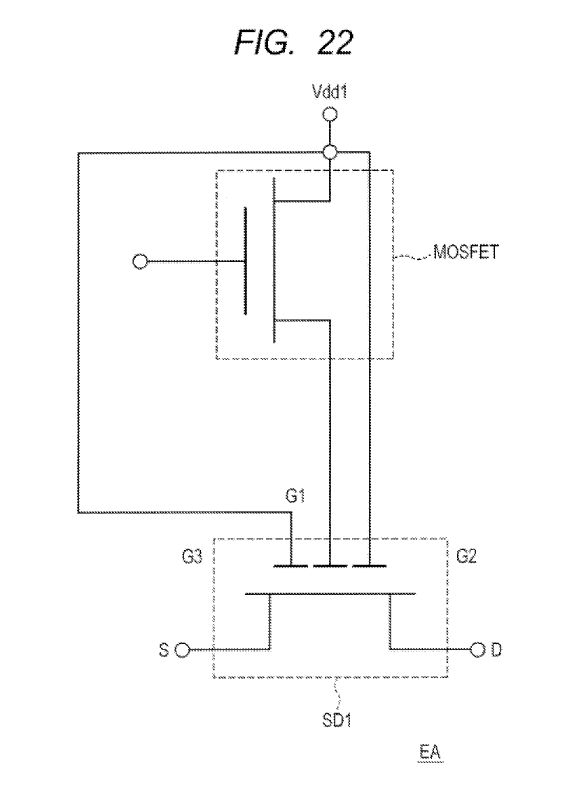

FIG. 22 through FIG. 24 are circuit diagrams showing the electronic device EA containing semiconductor device SD1. In addition to the semiconductor device SD1, the electron device EA contains a MOSFET (Metal-Oxide-Semiconductor Field Effect Transistor). In FIG. 22 through FIG. 24, G1, G2, and G3 respectively correspond to the gate electrode GE, the first field plate FP1, and the second field plate FP2.

In FIG. 22, the electronic device EA includes power supply wire electrically coupled to the power supply (Vdd1). The first field plate FP1 and the second field plate FP2 are electrically coupled to the power supply wire. One of either the drain or source of the MOSFET is electrically coupled to the power supply wire. Moreover, the gate electrode GE is electrically coupled to the other drain or source of the MOSFET. The voltage potential of the first field plate FP1 and the voltage potential of the second field plate FP2 are in this way clamped at Vdd1 in the electronic device EA.

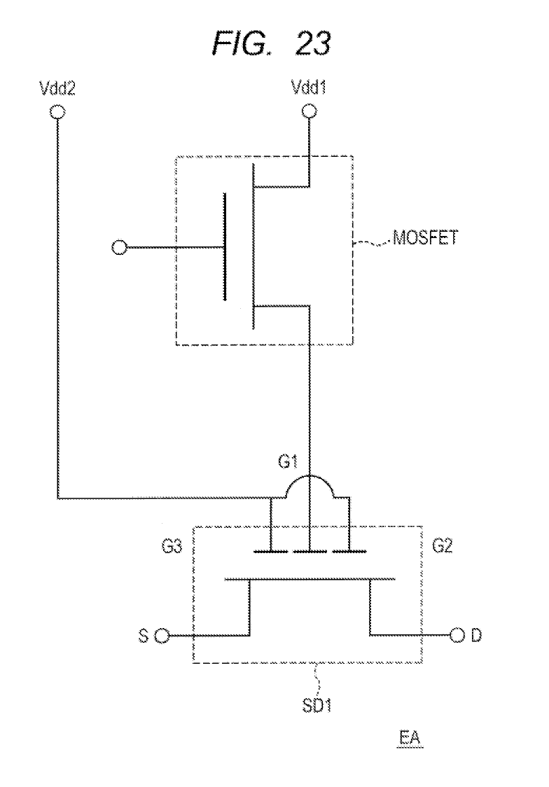

The electronic device EA in FIG. 23 contains a first power supply wire electrically coupled to the first power supply (Vdd1) and a second power supply wire electrically coupled to the second power supply (Vdd2). Either the drain or source of the MOSFET is electrically coupled to the first power supply wire. The first field plate FP1 and the second field plate FP2 are electrically coupled to the second power supply. Moreover, the gate electrode GE is electrically coupled to the other drain or source of the MOSFET. The voltage potential of the first field plate FP1 and the voltage potential of the second field plate FP2 are in this way clamped at Vdd2 in the electronic device EA.

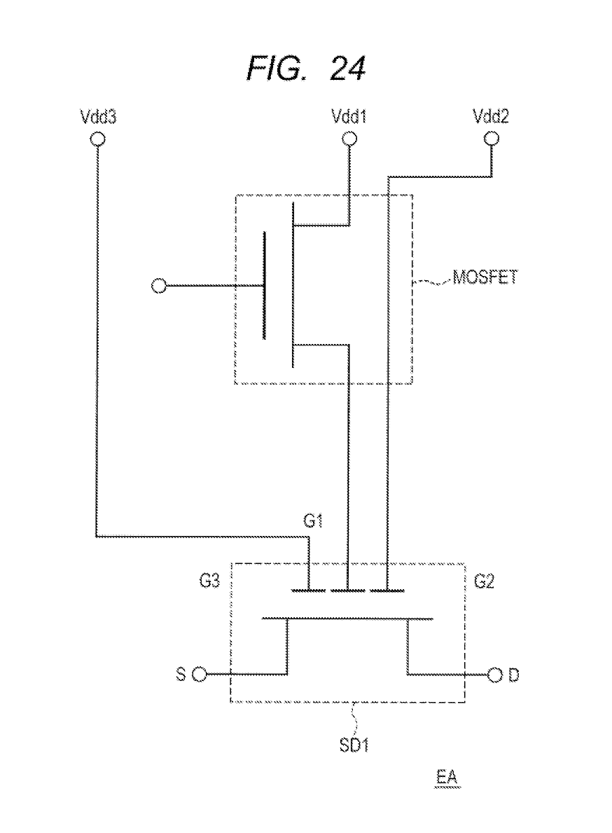

The electronic device EA in FIG. 24 contains a first power supply wire electrically coupled to the first power supply (Vdd1), a second power supply wire electrically coupled to the second power supply (Vdd2), and a third power supply wire electrically coupled to the third power supply (Vdd3). Either the drain or source of the MOSFET is electrically coupled to the first power supply wire. The first field plate FP1 is electrically coupled to the second power supply wire. The second field plate FP2 is electrically coupled to the third power supply wire. The gate electrode GE is electrically coupled to the other source or drain of the MOSFET. The voltage potential of the first field plate FP1 and the voltage potential of the second field plate FP2 are in this way respectively clamped at Vdd2 and Vdd3 in the electronic device EA.

The semiconductor device SD2 may be utilized instead of the semiconductor device SD1 in the electronic device EA. In the electronic device EA in FIG. 22 and FIG. 23, the first field plate FP1 and the second field plate FP2 are the same voltage potential. The semiconductor device SD2 can therefore be utilized in the electronic device EA in FIG. 22 and FIG. 23.

A bipolar transistor may be utilized instead of a MOSFET in the electronic device EA. In this case, the base, the collector, and the emitter of the bipolar transistor respectively correspond to the gate, the drain, and the source of the MOSFET.

The invention rendered by the present inventors is specifically described based on the embodiments as described above. The present invention however is not limited by the embodiments and all manner of changes not departing from the spirit and scope of the present invention are allowable.

What is claimed is:

1. A semiconductor device comprising:
a first group-III nitride semiconductor layer;
a second group-III nitride semiconductor layer formed over the first group-III nitride semiconductor layer;
an insulation layer that includes a first surface and a second surface facing opposite the second group-III nitride semiconductor layer by way of the first surface, and the second surface contains an aperture whose bottom reaches at least the inner side of the second group-III nitride semiconductor layer;
a drain electrode and a source electrode that are electrically coupled to the second group-III nitride semiconductor layer, and facing mutually opposite each other by way of the aperture as seen from a plan view;
a gate electrode of which at least a portion faces opposite the first group-III nitride semiconductor layer by way of the bottom of the aperture along the depth direction of the aperture; and
a first field plate of which at least a portion faces opposite the second group-III nitride semiconductor layer by way of the insulation layer between the aperture and the drain electrode as seen from a plan view,
wherein the aperture includes a first side wall that is positioned on the side of the drain electrode, and a second side wall that is positioned on the side of the source electrode,
wherein the gate electrode includes a first side surface facing opposite the drain electrode as seen from a plan view, and the first side surface is positioned on the inner side of the first side wall and the second side wall as seen from a plan view,
wherein a portion of the first field plate is embedded between the first side surface and the first side wall, and
wherein at least a portion of the gate electrode and the first field plate are electrically insulated by a first insulation member that is positioned on the inner side of the first side wall and the second side wall as seen from a plan view.

2. The semiconductor device according to claim 1, further comprising:
a second field plate of which at least a portion faces opposite the second group-III nitride semiconductor layer by way of the insulation layer between the aperture and the source electrode as seen from a plan view,
wherein the gate electrode includes a second side surface facing opposite the source electrode as seen from a plan view, and the second side surface is positioned on the inner side of the first side wall and the second side wall as seen from a plan view,
wherein a portion of the second field plate is embedded between the second side surface and the second side wall, and
wherein at least a portion of the gate electrode and the second field plate are electrically insulated by a second insulation member that is positioned on the inner side of the first side wall and the second side wall as seen from a plan view;

3. The semiconductor device according to claim 1,
wherein the first field plate and the drain electrode are formed separated from each other as seen from a plan view, in a direction facing opposite the drain electrode and the source electrode.

4. The semiconductor device according to claim 2,
wherein the first field plate and the drain electrode are formed separated from each other as seen from a plan view, in a direction facing opposite the drain electrode and the source electrode,
wherein the second field plate and the source electrode are formed separated from each other as seen from a plan view, in a direction facing opposite the drain electrode and the source electrode.

5. The semiconductor device according to claim 4,
wherein the first field plate includes a first edge section facing opposite the drain electrode as seen from a plan view, in a direction facing opposite the drain electrode and the source electrode,
wherein the second field plate includes a second edge section facing opposite the source electrode as seen from a plan view, in a direction facing opposite the drain electrode and the source electrode, and
wherein the gap between the first edge section and the drain electrode is larger than the gap between the second edge section and the source electrode in a direction facing opposite the drain electrode and source electrode.

6. The semiconductor device according to claim 1,
wherein the first side surface is closer to the drain electrode side than the center of the aperture, in a direction facing opposite the first side wall and the second side wall as seen from a plan view.

7. The semiconductor device according to claim 2,
wherein the width of the gate electrode is wider than each width of the section formed so as to embed the portion of the first field plate between the first side surface and the first side wall, and the width of the section formed so as to embed the portion of the second field plate between the second side surface and the second side wall, in a direction facing opposite the first side wall and the second side wall as seen from a plan view.

8. The semiconductor device according to claim 1,
wherein a conductive film is formed from the aperture to the side of the drain electrode, a groove is formed on the inner side of the first side wall and the second side wall as seen from a plan view, and a first insulation material is embedded in at least a portion of the groove;
wherein the conductive film forms a gate electrode at the side of the source electrode relative to the first insulation member as seen from a plan view, and also forms the first field plate on the side of the drain electrode relative to the first insulation member as seen from a plan view.

9. The semiconductor device according to claim 2,
wherein an insulation film is formed from the inner side of the aperture to the outer side of the aperture as seen from a plan view, and the insulation film is formed along the contour of the gate electrode and the aperture on the inner side of the aperture as seen from a plan view,
wherein along with forming a conductive film from the inner side of the aperture to the outer side of the aperture as seen from a plan view, the conductive film also covers the gate electrode and the insulation film,
wherein along with forming the first insulation member along the first side surface, the insulation film forms the second insulation member along the second side surface, and
wherein the conductive film forms the first field plate from the aperture to the drain electrode as seen from a plan view, and also forms the second field plate from the aperture to the source electrode as seen from a flat view.

10. The semiconductor device according to claim 4,
wherein the first field plate includes a first edge section facing opposite the drain electrode as seen from a flat view, in a direction facing opposite the drain electrode and the source electrode,
wherein the second field plate includes a second edge section facing opposite the source electrode as seen from a flat view, in a direction facing opposite the drain electrode and the source electrode,
wherein the width between the first side wall and the first edge section is wider than the width between the second side wall and the second edge section in the direction facing opposite the drain electrode and the source electrode, and
wherein the aperture is closer to the source electrode side rather than the drain electrode, in a direction facing opposite the drain electrode and the source electrode.

11. A semiconductor device comprising:
a first group-III nitride semiconductor layer;
a second group-III nitride semiconductor layer formed over the first group-III nitride semiconductor layer;
an insulation layer that includes a first surface, and a second surface facing opposite the second group-III nitride semiconductor layer by way of the first surface, and the second surface contains an aperture whose bottom reaches at least the inner side of the second group-III nitride semiconductor layer;
a drain electrode and a source electrode electrically coupled to the second group-III nitride semiconductor layer, and facing opposite each other by way of the aperture as seen from a plan view;
a gate electrode of which at least a portion faces opposite the first group-III nitride semiconductor layer by way of the bottom of the aperture along the depth direction of the aperture;
a first field plate of which at least a portion faces opposite the second group-III nitride semiconductor layer by way of the insulation layer between the aperture and the drain electrode as seen from a plan view; and
a drain pad, a source pad, a gate pad, and a first electrode pad respectively electrically coupled to the drain electrode, the source electrode, the gate electrode, and the first field plate,
wherein the gate electrode and the first field plate are electrically insulated by way of the first insulation member, and
wherein the first electrode pad is formed at a position different from the drain pad, the source pad, and the gate pad.

12. The semiconductor device according to claim 11, further comprising:
a second field plate of which at least a portion faces opposite the second group-III nitride semiconductor layer by way of the insulation layer between the aperture and the source electrode as seen from a plan view; and
a second electrode pad electrically coupled to the second field plate,
wherein the gate electrode and the second field plate are electrically insulated by way of the second insulation member, and
wherein the second electrode pad is formed at a position different from the drain pad, the source pad, and the gate pad.

13. The semiconductor device according to claim 12,
wherein the first electrode pad and the second electrode pad are identical electrode pads.

14. The semiconductor device according to claim 12,
wherein the first electrode pad and the second electrode pad are different electrode pads.

15. The semiconductor device according to claim 12, further comprising:
a power supply wire; and
a MOSFET (Metal-Oxide-Semiconductor Field Effect Transistor),
wherein along with electrically coupling the first field plate and the second field plate to the power supply wire, either the drain or source of the MOSFET is electrically coupled to the power supply wire, and
wherein the gate electrode is electrically coupled to the other drain or source of the MOSFET.

16. The semiconductor device according to claim 12, further comprising:
a first power supply wire;
a second power supply wire; and
a MOSFET,
wherein either the drain or source of the MOSFET is electrically coupled to the first power supply wire,
wherein the first field plate and the second field plate are electrically coupled to the second power supply wire, and
wherein the gate electrode is electrically coupled to the other drain or source of the MOSFET.

17. The semiconductor device according to claim 12, further comprising:
a first power supply wire;
a second power supply wire;
a third power supply wire; and
a MOSFET,
wherein either the drain or source of the MOSFET is electrically coupled to the first power supply wire,
wherein the first field plate is electrically coupled to the second power supply wire,
wherein the second field plate is electrically coupled to the third power supply wire, and
wherein the gate electrode is electrically coupled to the other drain or source of the MOSFET.

18. The semiconductor device according to claim 13,
wherein the drain pad and the source pad face opposite each other by way of the gate electrode, the first field plate, and the second field plate as seen from a plan view,
wherein the gate pad is positioned towards either of the sides of the drain pad or the source pad in a direction facing opposite the drain electrode and the source electrode, and
wherein the electrode pad is positioned towards the side of the gate pad in a direction facing opposite the drain pad and the source pad.

19. The semiconductor device according to claim 18,
wherein the electrode pad is positioned between the drain pad and the source pad in a direction facing opposite the drain pad and the source pad.

20. The semiconductor device according to claim 18,
wherein the drain electrode extends from the side of the drain pad towards the side of the source pad as seen from a plan view,
wherein the source electrode extends from the side of the source pad to the side of the drain pad as seen from a flat view,
wherein the gate electrode is positioned between the drain electrode and the source electrode as seen from a plan view, and
wherein a meandering pattern is formed so as to weave between the drain electrode and the gate electrode, and between the source electrode and the gate electrode; and the meandering pattern forms the first field plate between the drain electrode and the gate electrode, and also forms the second field plate between the source electrode and the gate electrode.
